(19) United States
(12) Patent Application Publication
(10) Pub. No.: US 2008/0089376 A1
(43) Pub. Date: Apr. 17, 2008

(54) Current Confining Structure and Semiconductor Laser

(76) Inventor: Takayoshi Anan, Tokyo (JP)

Correspondence Address: Paul J. Esatto Jr.;Scully, Scott, Murphy & Presser, P.C., 400 Garden City Plaza, Suite 300, Garden City, NY, 11530, US

(21) Appl. No.: 11/663,320

(22) PCT Filed: Sep. 8, 2005
(86) PCT No.: PCT/JP05/16485

§ 371 Date: Mar. 20, 2007

(30) Foreign Application Priority Data
Sep. 21, 2004 (JP) 2004-273066

(51) Int. Cl. H01S 5/30; H01S 5/32

(52) U.S. Cl. 372/46.013

(57) ABSTRACT

To provide such a technique as to solve problems about a high operating voltage, temperature rise due to heat generation, in-plane non-uniform injection, and a small modulation bandwidth upon high-speed modulation in a surface-emitting laser. A current confining structure according to the present invention includes an n-type semiconductor layer 102, a current confining layer 106, a current-diffusion preventing layer 103, an active layer 104, and a p-type semiconductor layer 105, which are laminated in order on an n-type semiconductor substrate 101. The current confining layer 106 is composed of a current carrying layer 106b and a current blocking layer 106a. The current-diffusion preventing layer 103 includes an n-type or undoped dilute nitrogen-based compound semiconductor layer containing 0.1% or more of nitrogen.

### TECHNICAL FIELD

The present invention relates to a current confining structure and a semiconductor laser using the same. In particular, the invention relates to a current confining structure for confining a current generated by n-type carriers, and a semiconductor laser using the same.

### BACKGROUND ART

General semiconductor lasers use a current confining structure to increase a carrier density in an active layer portion. Edge emitting semiconductor lasers adopt a current blocking structure obtained by embedding or ion-implanting or mesa-type ridge structure as a current confining structure. Meanwhile, as for surface-emitting lasers, an oxidized current confining structure obtained by selectively oxidizing an Al(Ga)As layer as well as current blocking structure obtained by ion implantation have been well known as a current confining structure. In this structure, after a layer structure of a device is completely grown, an Al(Ga)As layer is partially and selectively oxidized from a mesa side surface in accordance with a steam oxidation process to obtain a highly insulative oxidized current blocking layer and allow a current to flow only through unoxidized areas.

According to this technique, semiconductor layers are formed through epitaxial growth on a flat substrate, so composition and thickness of each layer can be controlled with accuracy, leading to high yield. Further, a refractive index of the oxidized current blocking layer is smaller than that of its surrounding semiconductor, so an effect of confining light in a transverse direction and a threshold current of laser can be reduced. As described above, the oxidized current confining structure has been widely used as a current confining structure especially for a surface-emitting laser made of a GaAs-based material.

FIG. 6 is a schematic sectional view of an oxidized current confining structure of a typical surface-emitting laser. An n-type semiconductor multilayer reflective film 202, an n-type clad layer 203, an active layer 204, a p-type clad layer 205, a current confining layer 206, and a p-type semiconductor multilayer reflective film 207 are layered in this order on an n-type semiconductor substrate 201, and a p-side electrode 208 and an n-side electrode 209 are formed by a given process. The current confining layer 206 includes a current blocking layer 206a and a current carrying layer 206b.

If a current flows through the surface-emitting laser, the current injected from the upper electrode 208 is passed through the p-type semiconductor multilayer reflective film 207 and then confined in the current carrying layer 206b. The confined current spreads a little in the p-type clad layer 205 and flows into the active layer 204. The current confining structure aims at increasing a carrier density in the active layer 204. From this point of view, the current confining layer 206 and the p-type clad layer 205 mainly contribute to current confinement. That is, it is necessary that while the current confining layer 206 confines a current and keeps the confined shape as much as possible, a current is injected to the active layer 204.

To that end, it is necessary to prevent a current from spreading in the p-type clad layer 205 as much as possible. The conventional current confining structure is formed on the p-type semiconductor layer side. This is because a carrier mobility of a p-type semiconductor layer is generally as low as 1/10 or less of an n-type semiconductor layer and thus, its in-plane resistance is high, thereby making it possible to reduce the degree to which a current spreads during a period from current confinement to current injection to the active layer 204 (see Non-Patent Document 1, for instance).

In contrast, a current confining structure that confines a current in an n-type conductive layer, not a p-type semiconductor layer has been known (Patent Document 1). In the structure as disclosed in Patent Document 1, an AlGaAs layer containing more than 0.4 as Al composition is used as a current-diffusion preventing layer in order to realize n-side current confinement. It is experimentally demonstrated that an electron (n-type carrier) mobility of the AlGaAs layer having an Al composition of 0.4 or more is at least 1/10- 1/30 of that of GaAs due to Γ-x crossover or DX center at the lower end of a conduction band. Since, this value is almost equal to a hole mobility, as high current confining effect as that of the p-type current confining structure can be expected. If the n-side current confining structure is used for a surface-emitting laser on a p-type substrate, an improvement effect of minimizing a process damage on an active layer, an improvement effect of heat liberation, and the like are expected.

[Non-Patent Document 1]

Kent. D. Choquette et al., “Applied Physics Letters” 1995, Vol. 66, pp. 3413-3415

[Patent Document 1]

Japanese Unexamined Patent Application Publication No. 2004-146515 (pp. 5-7, FIG. 1)

### DISCLOSURE OF THE INVENTION

### Problems to be Solved by the Invention

However, the semiconductor laser structure as disclosed in Non-Patent Document 1 has some problems. The first problem is that the smaller the confined-current path diameter, the larger the resistance of the whole element. FIG. 7 shows a carrier moving path in the case where a current confining structure is formed in a conventional p-type semiconductor layer. The current confining layer 206 confines a current (hole (p-type) carrier) to thereby realize a high carrier density in the active layer 204.

The p-type semiconductor multilayer reflective film 207 above the current confining layer 206 has a small mobility because of p-type semiconductor layer, and a current is prevented from spreading even in a portion 210 just above the current confining layer 206. The p-type semiconductor multilayer reflective film 207 is formed through heterojunction between materials having a large refractive index difference, so a resistance to a hole having large effective mass per unit area at a heterointerface is large. Thus, a resistance in the portion 210 as well as the current confining layer 206 increases, and a resistance of the whole element increases.

Further, current concentration occurs in the current confining layer 206 and the portion 210 just above the layer 206, but carriers are holes the mobility of which is small, so in-plane uniformity is very low. That is, the current density is large at the edge of the current carrying layer 206b (region near the current blocking layer 206a), and is small at the center as compared with the edge. This is the second problem.

As described above, if the oxidized current confining structure is formed on the p-type semiconductor layer side, an electric resistance increases, with the result that an operating voltage increases and a junction temperature rises due to heat generation, which hinders an element high-temperature operation or high-output operation. Further, current density nonuniformity in the current carrying layer 206b leads to in-plane nonuniformity of the injected current in the active layer 204. As a result, a high-order transverse mode tends to appear and in turn, spatial hole burning tends to occur, leading to many characteristic deteriorations such as reduction in modulation bandwidth upon high-speed modulation.

On the other hand, in the semiconductor laser structure that adopts an n-type AlGaAs layer having an Al composition of 0.4 or more for a current-diffusion preventing layer as disclosed in Patent Document 1 has the following problems. A low carrier mobility of the semiconductor layer is attributed to the Γ-X crossover or DX center at the lower end of the conduction band. The above cannot be applied to layers made of other materials. That is, in the case of using the n-type current confining structure, an n-type AlGaAs semiconductor layer having an Al composition of 0.4 or more needs to be formed between a current confining layer and an active layer, and the degree of freedom of design is largely limited. Considering a long-wavelength surface-emitting laser, for example, under the condition that a quantum well is used as an active layer and an n-side barrier layer adjacent thereto is an n-type AlGaAs semiconductor layer having an Al composition of 0.4 or more, band discontinuity of both of a conduction band and a valence band becomes large, and a quantum level energy increases. Hence, it is difficult to realize a long-wavelength laser.

Further, in light of the growth as well, relatively high temperature is generally necessary as growth temperature of an AlGaAs semiconductor layer having large Al composition, but a lower temperature growth is suitable for, for example, a strained quantum well to prevent three-dimensional growth. If the layers are continuously formed, a very long waiting time is necessary for changing a temperature, and a non-radiative center at an interface between layers during growth increases, leading to deteriorations in element characteristics. Further, in the case where the material grows based on metalorganic chemical vapor deposition, Al is readily mixed into the N-contained layer. It is known that if an Al-contained material grows up to the N-contained layer and the active layer is a GaInNAs layer, for example, a large amount of Al is mixed into the active layer to largely deteriorate laser characteristics. As described above, if the current-diffusion preventing layer is formed of an AlGaAs-based material, the degree of freedom of design of band structure is small, which accompany many limitations and difficulties in terms of crystal growth.

The present invention has been accomplished in light of the above circumstances. An object of the present invention is to provide a current confining structure having high degree of freedom of design and a semiconductor laser using the same.

### Means for Solving the Problems

According to a first aspect of the present invention, a current confining structure includes: an n-type semiconductor layer; an active layer; a current confining layer formed between the active layer and the n-type semiconductor layer and confining a current derived from n-type carriers moving from the n-type semiconductor layer to the active layer; and a current-diffusion preventing layer formed between the current confining layer and the active layer and including a nitrogen-based compound semiconductor layer obtained by substituting nitrogen atoms for a part of atoms of a base compound semiconductor. According to this structure, a current confining structure that enables high degree of freedom of design can be provided.

The nitrogen-based compound semiconductor layer may be an n-type or undoped layer. Further, the nitrogen-based compound semiconductor layer may be formed of a material selected from the group consisting of GaAsN, AlGaNAs, GaInNP, GaAsNP, and GaInNAs.

The nitrogen-based compound semiconductor layer preferably contains 0.05% or more of nitrogen. Hence, an n-type carrier mobility can be reduced enough. The current-diffusion preventing layer includes the nitrogen-based compound semiconductor layer and the AlₓGa₁₋ₓAs layer having Al composition of 0.4 or more to thereby increase the degree of freedom of design. Further, the structure preferably further includes a p-type semiconductor layer formed across the active layer from the n-type semiconductor layer, the p-type semiconductor layer including a current diffusion layer promoting current in-plane diffusion.

The current confining layer may be formed by selectively oxidizing an AlₓGa₁₋ₓAs semiconductor layer (0.95≦x≦1) or may include a current carrying layer made of an n-type semiconductor and a p-type semiconductor current blocking layer formed around the current carrying layer.

According to a second aspect of the present invention, a semiconductor laser includes: a semiconductor substrate; a p-type semiconductor layer and an n-type semiconductor layer laminated on a surface of the semiconductor substrate; an active layer formed between the p-type semiconductor layer and the n-type semiconductor layer; a current confining layer formed between the active layer and the n-type semiconductor layer and confining a current derived from n-type carriers moving from the n-type semiconductor layer to the active layer; a current-diffusion preventing layer formed between the current confining layer and the active layer and including a nitrogen-based compound semiconductor layer obtained by substituting nitrogen atoms for a part of atoms of a base compound semiconductor; and an optical resonator structure for inducing laser oscillation. According to this structure, a semiconductor laser that enables high degree of freedom of design and low operating voltage can be provided.

The nitrogen-based compound semiconductor layer preferably contains 0.05% or more of nitrogen. The optical resonator structure includes semiconductor multilayer reflective films sandwiching the active layer, and laser light is emitted vertically to the surface of the semiconductor substrate. Alternatively, the current diffusion layer is preferably formed at a node of light field intensity.

### ADVANTAGES OF THE INVENTION

According to the present invention, it is possible to attain an n-type current confining structure having high degree of freedom of design.

### BRIEF DESCRIPTION OF THE DRAWINGS

FIG. 1 is a sectional view of a current confining structure according to an embodiment of the present invention;

FIG. 2 is a sectional view of a semiconductor laser structure according to another embodiment of the present invention;

FIG. 3 is a graph showing a relation between N composition x of n-type GaAsNx and an electron mobility;

FIG. 4 is a sectional view of a semiconductor laser structure according to a specific example of the present invention;

FIG. 5 is a sectional view of a semiconductor laser structure according to a specific example of the present invention;

FIG. 6 is a sectional view of a surface-emitting laser element of the Related Art; and

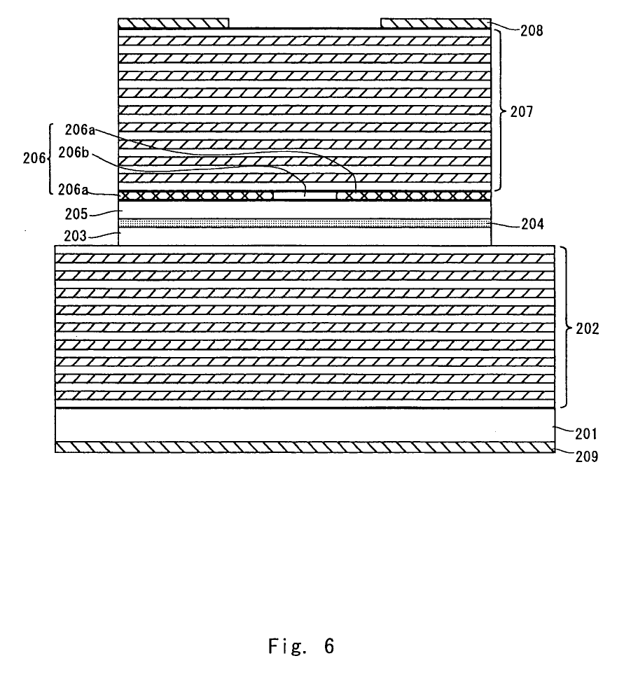

FIG. 7 is a schematic diagram of current confinement in a surface-emitting laser element of the Related Art.

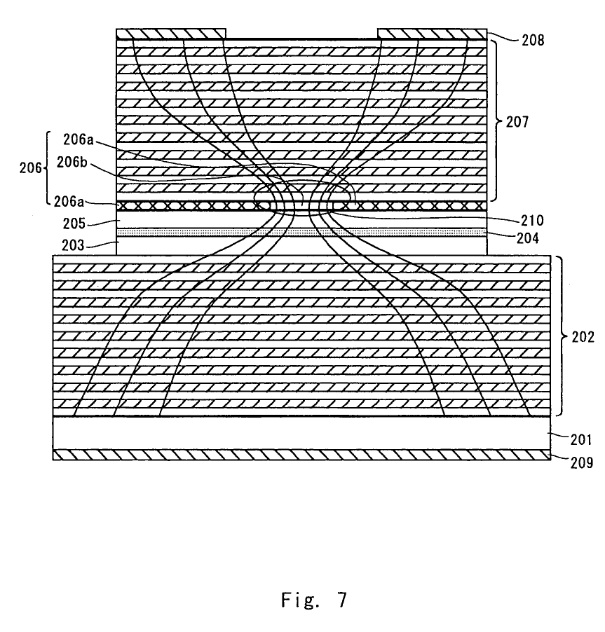

### DESCRIPTION OF REFERENCE NUMERALS

101 n-type semiconductor substrate
102 n-type semiconductor layer
102a n-type semiconductor multilayer reflective film
102a1 Si-doped Al_{0.9}Ga_{0.1}As layer
[[102b1]] 102a2 Si-doped GaAs layer
103 current-diffusion preventing layer
103a Si-doped Al_{0.2}Ga_{0.8}As_{99.9%}N_{0.1%} layer
103b undoped GaAs_{99.8%}N_{0.2%} layer
104 active layer
104a undoped Ga_{0.65}In_{0.35}N_{1%}As_{99%} quantum well layer
104b undoped GaAs_{98.6%} N_{1.4%} barrier layer
105 p-type semiconductor layer
105a carbon (C)-doped AlGaAs graded layer
105b p-type semiconductor multilayer reflective film
105b1 C-doped Al_{0.9}Ga_{0.1}As layer
105b2 C-doped GaAs layer
105c undoped GaAs_{99.8%}N_{0.2%} layer
105d undoped GaAs layer
105e undoped In_{0.2}Ga_{0.8}As layer
106 current confining layer
106a current blocking layer
106b current carrying layer
107 p-side electrode
108 n-side electrode
109 intermediate layer portion
201 n-type semiconductor substrate
202 n-type semiconductor multilayer reflective film
203 n-type clad layer
204 active layer
205 p-type clad layer
206 current confining layer
206a current blocking layer
206b current carrying layer
207 p-type semiconductor multilayer reflective film
208 p-side electrode
209 n-side electrode
210 portion just above current confining layer

### BEST MODES FOR CARRYING OUT THE INVENTION

Hereinafter, embodiments of the present invention will be described. The following description is given for explaining embodiments of the present invention, and the present invention is not limited to the following embodiments. For ease of explanation, the following description and the accompanying drawings are appropriately omitted and simplified.

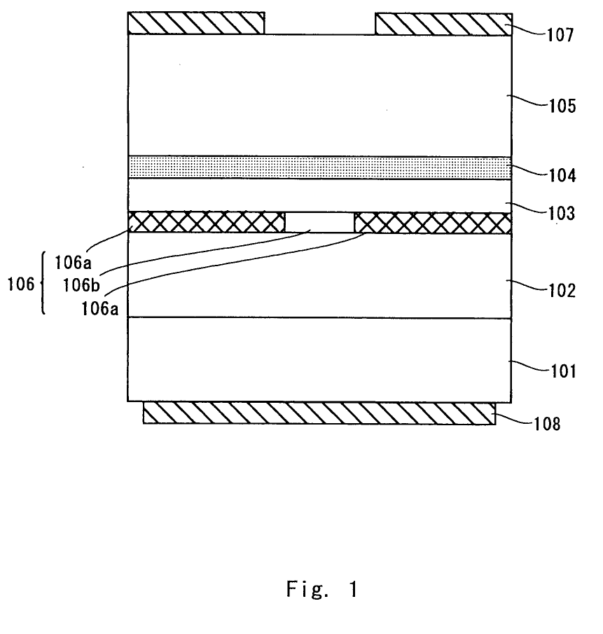

Referring to FIG. 1, the basic structure of a current confining structure according to an embodiment of the present invention is described below. An n-type semiconductor layer 102, a current confining layer 106, a current-diffusion preventing layer 103, an active layer 104, and a p-type semiconductor layer 105 are layered in this order on one side of an n-type semiconductor substrate 101. The current confining layer 106 is composed of a current carrying layer 106b and a current blocking layer 106a. A p-side electrode 107 is formed on the p-type semiconductor layer 105, and an n-side electrode 108 is formed on the other side of the n-type semiconductor substrate 101, that is, the side opposite to the n-type semiconductor layer 102. A current can be externally injected to the active layer 104 through the electrodes 107 and 108. The current-diffusion preventing layer 103 has an n-type or undoped nitrogen-based compound semiconductor layer. Here, the nitrogen-based compound semiconductor layer refers to a layer obtained by substituting nitrogen atoms for some atoms of a base compound semiconductor. In this embodiment, a dilute nitrogen compound semiconductor containing a small amount of nitrogen is used.

The externally injected current is confined into a desired diameter by the current carrying layer 106b of the current confining layer 106 and then converted into light through radiative recombination between electrons and holes in the active layer 104. In this example, the current confining layer 106 is formed adjacent to the n-type semiconductor layer 102 and functions to confine electron carriers (n-type carriers). The current-diffusion preventing layer 103 functions to guide the confined electron carriers to the active layer 104 while limiting a path of the carriers. To realize the function, the current-diffusion preventing layer 103 has a dilute nitrogen-based compound semiconductor layer. An electron mobility of the dilute nitrogen-based compound semiconductor layer is much lower than an electron mobility of a general direct transition-type semiconductor to thereby suppress transverse dispersion of electron carriers. Thus, even an n-type current confining structure for confining electron carriers can exert a high current confining effect. Incidentally, the dilute nitrogen-based compound semiconductor layer is detailed later.

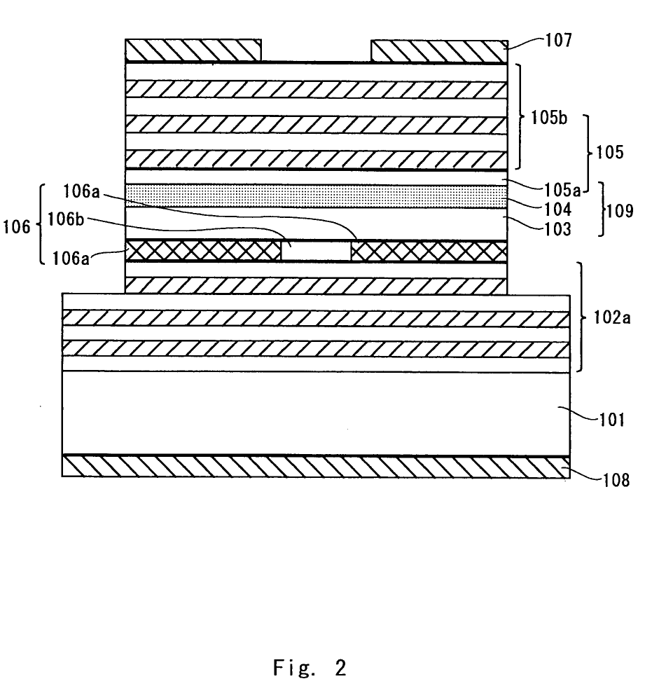

The above description is focused on the basic structure and operations of the n-type current confining structure of this embodiment. To apply these to an actual device, the layer structure should be described in more detail based on the above structure. FIG. 2 shows the layer structure if the current confining structure of this embodiment is applied to the surface-emitting laser. The main difference from the structure of FIG. 1 is that the n-type semiconductor layer 102 is formed as an n-type semiconductor multilayer reflective film 102a. In addition, a part of the p-type semiconductor layer 105 is formed as a p-type semiconductor multilayer reflective film 105b. These films function as a pair of reflective films for emitting light in the direction vertical to the substrate surface.

Further, a part of the p-type semiconductor layer 105 is formed as a p-type semiconductor graded layer 105a. The current-diffusion preventing layer 103, the active layer 104, and the p-type semiconductor graded layer 105a constitute an intermediate layer 109. A cavity length of the intermediate layer 109 is set synchronous with a reflection wavelength of the reflective films 102a and 105b to thereby complete a resonator structure, which operates as a surface-emitting laser. The functions of the current confining layer 106 and the current-diffusion preventing layer 103 are the same as above.

In the surface-emitting laser structure, the current confining layer 106 is adjacent to the n-type semiconductor multilayer reflective film 102a, an n-type semiconductor is formed around the current confining portion, and a current largely spreads in the n-type semiconductor multilayer reflective film 102a just below the current confining layer, with the result that an electric resistance is lowered. Further, in the n-type semiconductor, an optical-absorption coefficient due to n-type carriers (electrons) is small, so impurities can be doped to the n-type semiconductor multilayer reflective film 102a in a relatively large concentration, which contributes to further reduction in resistance. In addition, a current diffusion layer that promotes in-plane current diffusion is formed near the p-type semiconductor layer 105, in particular, near the active layer 104 in the p-type semiconductor layer 105, and current diffusion is enhanced as much as possible on the p-side to thereby further reduce an electric resistance on the p-side. An effect of lowering an operating voltage and an effect of preventing junction temperature from rising due to heat generation can be attained by reducing the electric resistance of the element this way.

Owing to the effect of current diffusion in the n-type semiconductor multilayer reflective film 102a, non-uniform carrier injection can be also suppressed, thereby making it possible to overcome a problem about a high-order mode resulting from non-uniform in-plane injection and a problem about a small modulation bandwidth upon high-speed modulation resulting from spatial hole burning. By configuring a semiconductor laser with the current confining structure of this embodiment in this way, a semiconductor laser that enables a low operating voltage, good temperature characteristics, high transverse-mode stability, and wide modulation bandwidth can be provided.

Incidentally, the above two embodiments describe the case where the current confining structure of the present invention is formed on the n-type semiconductor substrate 101. Incidentally, in the case of forming a current confining structure on a p-type semiconductor substrate, the layers on the thus-structured n-type semiconductor substrate 101 may be laminated in reverse order.

Subsequently, the current-diffusion preventing layer 103 of this embodiment is described in detail. In the current confining structure of this embodiment and the semiconductor laser using the same, to realize carrier confinement in the n-type current confining structure, a dilute nitrogen-based compound semiconductor layer having a small electron mobility is used for the current-diffusion preventing layer 103. A current diffusion amount in the current-diffusion preventing layer 103 varies depending on a resistance in the layer, a layer thickness and current value of the layer. As the resistance is high and the layer thickness is small, transverse current diffusion is suppressed. Among these parameters, a parameter largely influencing material physical properties is a resistance. In addition, the resistance is a function of carrier mobility and carrier concentration. The smaller the carrier mobility or carrier concentration, the larger the resistance and the current diffusion is more limited.

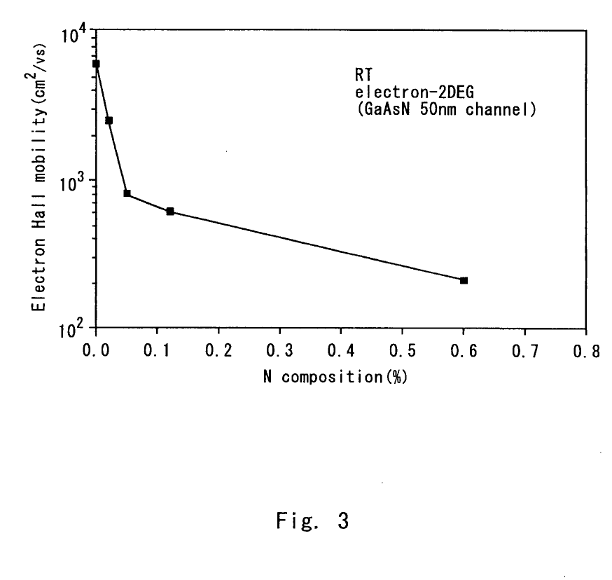

FIG. 3 shows an N-concentration dependency of an electron mobility of a GaAsN dilute nitrogen-based compound semiconductor layer obtained by adding a small amount of N to GaAs, at room temperature. As apparent from FIG. 3, if a very small amount of N is doped, an electron mobility is abruptly decreased. The reason the mobility is abruptly decreased with a small amount of N is supposedly fluctuations in potential due to doping of N. Thus, the reduction in mobility due to doping of N is utilized to compound semiconductors made of various materials used in the current-diffusion preventing layer. As described above, an electron mobility can be largely decreased by doping a very small amount of N, so various other physical properties of a base semiconductor material prior to doping of N (lattice constant, band gap, thermal resistance, and the like) can be kept. Thus, a desired material can be selected for the current-diffusion preventing layer without considering a change in physical properties due to doping of N. Hence, an n-type current confining structure having high degree of freedom of design and a semiconductor laser using the same can be provided.

If a current is too widely spread in the current-diffusion preventing layer 103, current confinement cannot be effectively realized. From this point of view, an electron mobility in the current-diffusion preventing layer 103 is 1000 cm²/V·sec or less, more preferably, 700 cm²/V·sec or less. Referring to FIG. 3, an electron mobility largely falls especially in an N concentration from 0 to 0.05% and then gradually lowers. Further, an electron mobility at an N concentration of 0.05% is 1000 cm²/V·sec or less. GaAs shows a large electron mobility relative to other compound semiconductor materials used in the n-type-carrier current-diffusion preventing layer 103, so an N concentration relative to the mobility can be determined based on the electron mobility in GaAs. Therefore, the N content of the dilute nitrogen-based compound semiconductor is preferably 0.05% or more, more preferably 0.1% or more.

As one preferred mode of the n-type current confining structure, an N dosage is determined such that the current-diffusion preventing layer 103 shows a carrier mobility not larger than the carrier mobility of the p-type current confining structure. For example, the p-type GaAs current confining structure typically shows a carrier mobility of about 400 cm²/V·sec. Accordingly, N is doped to the current-diffusion preventing layer 103 at a concentration of 0.3% or more such that an electron mobility of the n-type GaAs current confining structure is 400 cm²/V·sec. Meanwhile, an amount of atoms of the base compound semiconductor, which are replaceable by nitrogen atoms is limited in terms of crystal growth. In light of this, a concentration of N doped to the base compound semiconductor is preferably 5% or less, more preferably 3% or less.

Here, an amount of current diffusion of electron carriers in GaAs is estimated. To give a specific value, for example, a width L of the current carrying layer 106b is 5 μm, a layer thickness d of the current-diffusion preventing layer 103 is 200 nm, and a current value I of a portion just below the current carrying layer 106b is 10 mA. If a carrier concentration n=3×10¹⁷ cm⁻³, a mobility p is 6000 cm²/V·sec at the N concentration of 0%, so a resistivity ρ=3.5×10⁻³ Ω·cm. A current spread width l is 29 μm, and a current spread width on one side with respect to a current passage width of 5 μm is about 29 μm, so effective current confinement cannot be performed. In contrast, if the mobility p is 200 cm²/V·sec and the carrier concentration n is 3×10¹⁷ cm⁻³, for example, the resistivity ρ is 0.1 Ω·cm. In this case, the current spread width l on one side with respect to the width of the current carrying layer 106b is 1 μm, so current confinement can be sufficiently executed.

Here, as a current-diffusion preventing layer that can be laminated on the GaAs substrate, Al_{y}Ga_{1-y}NₓAs₁₋ₓ, Ga_{1-y}In_{y}NₓP₁₋ₓ, GaAs_{1-x-y}NₓP_{y}, Ga_{1-y}In_{y}As₁₋ₓNₓ, and the like are preferred aside from the foregoing GaAs₁₋ₓNₓ.

A GaAs₁₋ₓNₓ layer has substantially the same physical properties as those of GaAs and thus is used as a current-diffusion preventing layer adjacent to a GaIn(N)As quantum well layer to thereby attain the current confining effect and the long wavelength emission. However, as for a GaAsN-based material, there is a large discontinuity of conduction band (to 200 meV) between the material and a selectively oxidized current confining layer of the AlₓGa₁₋ₓAs semiconductor layer (0.95≦x≦1). Thus, if the above two are directly bonded, a large heterospike occurs.

The Al_{y}Ga_{1-y}NₓAs₁₋ₓ-based material is effective for eliminating the gap. In AlGaAs mixed crystal, the lowest bands in the conduction band intersect with each other (Γ-X crossover), so there is no energy barrier between a point X of AlAs and a point Γ of Al_{0.3}Ga_{0.7}As. However, there is an energy difference of about 200 meV between a point r of Al_{0.3}Ga_{0.7}As and a point r of GaAsN, so an Al_{y}Ga_{1-y}NₓAs₁₋ₓ-based material having an Al composition y that is gradedly varied (0<y≦0.3, x≧0.1%) is inserted between the AlGaAs layer and the GaAsN layer to thereby suppress an influence of the heterospike.

For example, Al_{0.1}Ga_{0.9}NₓAs₁₋ₓ is formed just below the GaAsN layer, Al_{0.2}Ga_{0.8}NxAs₁₋ₓ is formed below the Al_{0.1}Ga_{0.9}NₓAs₁₋ₓ layer, and Al_{0.3}Ga_{0.7}NₓAs₁₋ₓ is formed below the Al_{0.2}Ga_{0.8}NₓAs₁₋ₓ layer. In this way, plural [[Al_{0.2}Ga_{0.8}NₓAs₁₋ₓ]] AlGaNₓAs₁₋ₓ layers the Al composition of which is stepwise decreased from the AlGaAs layer toward the GaAsN layer are formed to thereby suppress an influence of the heterospike.

Further, as for a Ga_{1-y}In_{y}NₓP₁₋ₓ-based material, if an In composition y is about 0.49, lattice matching to the GaAs substrate is attained. To be specific, the current-diffusion preventing layer 103 having Ga_{0.51}In_{0.49}N_{0.02}P_{0.98} compositions can be formed. This material serves as an etching stop layer of an As-based mixed crystal semiconductor, and in addition, contains no Al as mentioned above. Hence, if the material and an N-based light emitting layer are used in combination, crystal having few non-radiative centers can be obtained.

In the GaAs_{1-x-y}NₓP_{y}-based material, P causes tensile strain in GaAs, so the material can be used for a strain compensation structure of an active layer having a compressive strain with respect to the GaAs substrate. More specifically, the current-diffusion preventing layer 103 can be formed of GaAs_{0.898}N_{0.02}P_{0.1}.

Further, in a Ga_{1-y}In_{y}As₁₋ₓNₓ-based material, the In composition and the N composition are appropriately changed to thereby change even a tensile strain into a compressive strain and considerably increase the degree of freedom of material. To be specific, the current-diffusion preventing layer 103 can be formed of Ga_{0.95}In_{0.05}As_{0.98}N_{0.02}.

Even a multilayer structure including plural layers different in elements may be used as the current-diffusion preventing layer. As the plural layers, the above dilute nitrogen-based compound semiconductor layers or the AlₓGa₁₋ₓAs layers having the Al composition of 0.4 or more as described in the Related Art may be used in combination. Thus, the degree of freedom of design of the current-diffusion preventing layer is further increased. In this case, it is preferred to insert the Al_{y}Ga_{1-y}NₓAs₁₋ₓ-based material having the Al composition y that gradedly varies (0≦y≦0.3, x≧0.1%) between the AlₓGa₁₋ₓAs layer having the Al composition of 0.4 or more and the GaAsN layer.

Several preferred materials for the current-diffusion preventing layer 103 are thus far described. Regarding layers other than the current-diffusion preventing layer 103, almost the same structure as that of the GaAs-based current-diffusion preventing layer 103 may be adopted. For example, a current diffusion layer that promotes in-plane current diffusion is formed in the p-type semiconductor layer 105 near the active layer 104 to thereby allow a current to spread as much as possible on the p-side to lower an electric resistance on the p-side.

### EXAMPLE 1

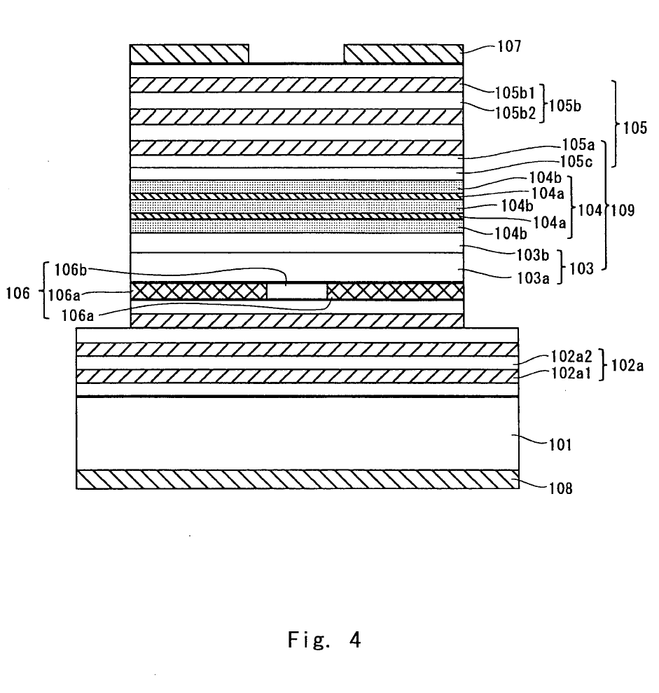

Referring next to FIG. 4, a current confining structure and a semiconductor laser according to Example 1 of the present invention are described below. Here, a surface-emitting laser having a wavelength of 1300 nm is described by way of example. The surface-emitting laser structure includes the n-type semiconductor multilayer reflective film 102a and the p-type semiconductor multilayer reflective film 105b, and the intermediate layer portion 109 sandwiched therebetween. Each portion is described in detail below.

An Si-doped Al_{0.9}Ga_{0.1}As layer 102a1 as a low refractive index layer and an Si-doped GaAs layer 102a2 as a high refractive index layer are paired, and 35 pairs of semiconductor multilayer reflective films 102a are first laminated in order on the Si-doped GaAs substrate 101 based on metalorganic chemical vapor deposition (MOCVD). Needless to say, molecular beam epitaxy (MBE) may be used. Incidentally, FIG. 4 illustrates only several pairs of semiconductor multilayer reflective films 102a. An Si-doped AlGaAs graded layer (not shown) is inserted between the low refractive index layer 102a1 and the high refractive index layer 102a2 to reduce an electric resistance. An Si-doped AlGaAs spacer layer (not shown) of an appropriate layer thickness and a selectively oxidized Si-doped Al_{0.97}Ga_{0.03}As layer 106 having a thickness of 40 nm are laminated thereon. At this point, 35.5 pairs of n-type multilayer reflective films are laminated by forming the semiconductor multilayer reflective film 102a and the selectively oxidized layer 106.

Next, as for the intermediate layer portion 109, the Si-doped Al_{0.2}Ga_{0.8}As_{99.9%}N_{0.1%} layer 103a and the undoped GaAs_{99.8%}N_{0.2%} layer 103b are laminated in this order on the selectively oxidized Al_{0.97}Ga_{0.03}As layer 106 to thereby form the current-diffusion preventing layer 103. The Si-doped Al_{0.2}Ga_{0.8}As_{99.9%}N_{0.1%} layer 103a suppresses an influence of heterospike due to a band discontinuity of conduction band between the undoped GaAs_{99.8%}N_{0.2%} layer 103b and the selectively oxidized Al_{0.97}Ga_{0.03}As layer 106.

Further, a double-quantum-well active layer is formed on the current-diffusion preventing layer 103. The double-quantum-well active layer include two 6 nm-thick undoped Ga_{0.65}In_{0.35}N_{1%}As_{99%} quantum well layers 104a, and three 30 nm-thick undoped GaAs_{98.6%}N_{1.4%} barrier layers 104b formed between the two quantum well layers 104a and outside the two quantum well layers 104a.

Subsequently, the undoped GaAs_{99.8%}N_{0.2%} layer 105c and the carbon (C)-doped AlGaAs graded layer 105a are laminated. The layers 103a to 105a constitute the intermediate layer portion 109. The intermediate layer portion 109 is designed to have such a layer thickness as to obtain resonance corresponding to one wave as optical length.

Subsequently, the p-type semiconductor multilayer reflective film 105b is formed. A C-doped Al_{0.9}Ga_{0.1}As layer 105b1 as a low refractive index layer and a C-doped GaAs layer 105b2 as a high refractive index layer are paired, and 25 pairs of layers are laminated in order to thereby complete the semiconductor multilayer reflective film 105b. Incidentally, FIG. 4 shows several pairs. The last layer is partially doped with C in a high concentration to readily get an ohmic contact on the p-side. Further, even a resistance of the p-type semiconductor multilayer reflective film is low, so a C-doped AlGaAs graded layer is inserted between the low refractive index layer and the high refractive index layer.

Regarding the band of the current-diffusion preventing layer 103, the lower end of the conduction band of the selectively oxidized Al_{0.97}Ga_{0.03}As layer 106 is the point X, while the lower end of the conduction band of the adjacent Al_{0.2}Ga_{0.8}As_{99.9%}NO_{0.1%} layer 103a is the point Γ; the Al_{0.2}Ga_{0.8}As_{99.9%}NO_{0.1%} layer 103a has an energy level about 40 meV lower than that of the layer 106 and thus is smoothly continuous to the subsequent GaAs_{99.8%} N_{0.2}% layer. If an AlGaAs layer having an Al composition of 0.4 or more with small electron mobility is used to form the portion, a potential barrier of about 100 meV occurs. The degree of freedom of band is increased by using a dilute nitrogen-based compound layer for the current-diffusion preventing layer 103.

The thus-obtained laminate structure is processed into a surface-emitting laser element through a general device process. First, a photoresist is applied to an epitaxial growth film to form a circular resist mask. Next, dry etching is executed until the underlying n-type multilayer reflective film 102a is exposed. Thus, a cylindrical structure having the diameter of about 30 μm is formed. Through the above process, a side surface of the current confining layer 106 is exposed.

Then, the obtained element is heated for about 10 minutes at the temperature of about 400 degrees in a water-vapor atmosphere. The Al composition of the selectively oxidized layer 106 is as large as 0.97 and is a little apart from the Al composition of 0.9 in the p-type semiconductor multilayer film, so an oxidization rate of the selectively oxidized layer 106 is high, the p-type semiconductor multilayer film is hardly oxidized, and the selectively oxidized layer 106 is selectively oxidized. As a result, the current blocking layer 106a is formed around the current confining layer 106, and the current carrying layer 106b having the diameter of about 8 μm is formed at the center thereof.

Next, the titanium (Ti)/gold (Au) ring-shaped p-side electrode 107 is formed on the mesa. Further, as an n-side electrode, the GaAs layer 102b in the n-type multilayer reflective film 102a is exposed and an AuGe-alloy n-type electrode 108 is formed in the exposed portion.

In the thus-manufactured surface-emitting laser, the n-type carrier current confinement is effectively performed, so low threshold characteristics equivalent to a conventional p-type carrier current confinement structure are obtained. Further, a current is not confined in the p-type semiconductor multilayer reflective film 105b, so an electric resistance of this portion is lowered, and a resistance of the entire element is reduced. Thus, heat generation during operation is suppressed, the maximum operating temperature is made high, and an optical output limited by heat generation can be increased. Further, in the n-type semiconductor multilayer reflective film 102a adjacent to the current confining layer, a current spreads more than the conventional p-type semiconductor multilayer reflective film 105b to thereby minimize carrier non-uniformity in the current carrying layer 106b. Hence, a problem about a high-order mode resulting from the in-plane non-uniform injection and a problem about reduction in modulation bandwidth resulting from spatial hole burning upon high-speed modulation can be solved.

### EXAMPLE 2

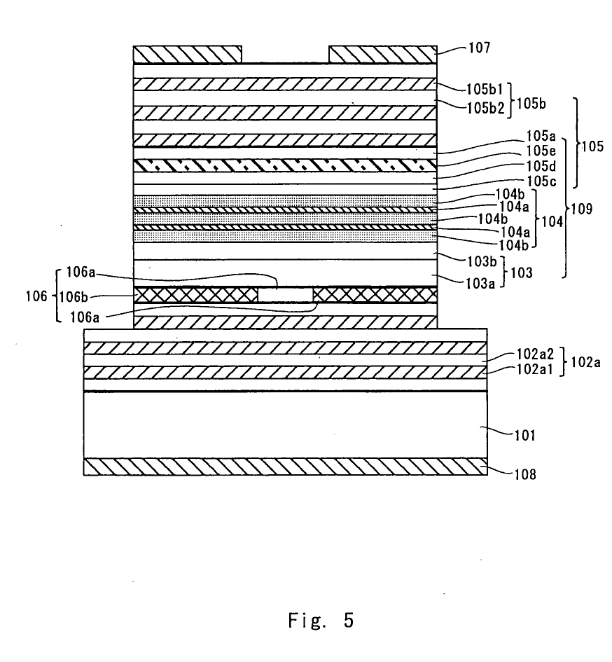

Referring next to FIG. 5, a current confining structure and a semiconductor laser according to Example 2 of the present invention is described below. This example also describes a surface-emitting laser having a wavelength of 1300 nm by way of example. Example 2 differs from Example 1 in that a current diffusion layer 105d is inserted at a light field intensity node of the p-type semiconductor layer 105. The n-type semiconductor multilayer reflective film 102a and the p-type semiconductor multilayer reflective film 105b are the same as those of Example 1, so the intermediate layer portion 109 is described in detail below.

As for the intermediate layer portion 109, the Si-doped Al_{0.2}Ga_{0.8}As_{99.9%}N_{0.1%} layer 103a and an undoped GaAs_{99.8%}N_{0.2}% layer are laminated in this order on the selectively oxidized Al_{0.97}Ga_{0.03}As layer 106 to form a current-diffusion preventing layer. Further, a double-quantum-well active layer is formed on the current-diffusion preventing layer 103. The double-quantum-well active layer includes two 6 nm-thick undoped Ga_{0.65}In_{0.35}N_{1%}As_{99%} quantum well layers 104a, and three 30 nm-thick undoped GaAs_{98.6%}N_{1.4%} barrier layers 104b formed between the two quantum well layers 104a and outside the two quantum well layers 104a.

Subsequently, the undoped GaAs_{99.8%}N_{0.2%} layer 105c and the undoped GaAs layer 105d are laminated. The 10 nm-thick undoped In_{0.2}Ga_{0.8}As current diffusion layer 105e and the carbon (C)-doped AlGaAs graded layer 105a are laminated in this order thereon. The layers 103a to 105a constitute the intermediate layer portion 109. The intermediate layer portion 109 is designed to have such a layer thickness as to obtain resonance corresponding to one wave as an optical length.

An undoped In_{0.2}Ga_{0.8}As layer having a compressive strain is used to form the current diffusion layer 105e, and holes from the adjacent carbon (C)-doped AlGaAs graded layer 105a are accumulated in the current diffusion layer 105e to generate a so-called two-dimensional hole gas. The current diffusion layer 105e is not directly influenced by ionized impurity scattering because of an undoped layer and thus has a large hole mobility. Further, the current diffusion layer 105e has a compressive strain, the large in-plane effective mass of holes due to the strain is smaller than GaAs, and its hole mobility is about three times as large as GaAs.

Thus, the two-dimensional hole gas generated in the current diffusion layer 105e has a large in-plane mobility, and holes can be dispersed in plane. Further, in this example, the active layer 104 is formed at the antinode of the field intensity, and the current diffusion layer 105e is formed at the node of the field intensity, that is ¼ wavelength away from the antinode, so holes accumulated in the current diffusion layer 105e do not involve a light absorption loss.

As described above, the obtained laminate structure is processed into a surface-emitting laser element through a device process similar to Example 1. As a result, in Example 2, since the p-side current diffusion layer is inserted, an electric resistance is much smaller than that of Example 1. Further, as for an oscillation threshold, the current diffusion layer is formed at the node of the field intensity, so a light absorption loss is minimized into a value substantially equal to that of Example 1.

This example describes the surface-emitting laser by way of illustration, but an edge emitting laser may be used. Further, the current-diffusion preventing layer of this example is made of two dilute nitrogen-based compound materials of different compositions, but more than two materials may be used. Alternatively, an AlGaAs layer having Al composition of 0.4 or more may be used in combination. Further, in this example, MOCVD is used as the crystal growth method, but MBE may be used. Here, as an emission wavelength of the surface-emitting laser, a wavelength of 1300 nm is described by way of example, but other wavelength may be used. Further, this example describes the n-type substrate by way of illustration, but a p-type substrate may be used.

The current confining structure of this example enables effective current confinement on the n-type side. Hence, an effect of lowering a resistance, an effect of controlling non-uniformity in carrier injection, an effect of suppressing an increase in operating voltage and an increase in junction temperature due to heat generation, an effect of suppressing high-order mode due to in-plane non-uniform injection, and an effect of increasing a modulation bandwidth upon high-speed modulation can be attained.

### INDUSTRIAL APPLICABILITY

The current confining structure according to the present invention is applicable to, for example, a semiconductor laser.

1. A current confining structure, comprising:
an n-type semiconductor layer;
an active layer;
a current confining layer formed between the active layer and the n-type semiconductor layer and confining a current derived from n-type semiconductor layer to the active layer; and
a current-diffusion preventing layer formed between the current confining layer and the active layer and including a nitrogen-based compound semiconductor layer obtained by substituting nitrogen atoms for a part of atoms of a base compound semiconductor.

2. The current confining structure according to claim 1, wherein the nitrogen-based compound semiconductor layer is an n-type or undoped layer.

3. The current confining structure according to claim 1, wherein the nitrogen-based compound semiconductor layer is formed of a material selected from the group consisting of GaAsN, AlGaNAs, and GaInNAs.

4. The current confining structure according to claim 1, wherein the current-diffusion preventing layer includes the nitrogen-based compound semiconductor layer and an AlₓGa₁₋ₓAs layer having Al composition of 0.4 or more.

5. The current confining structure according to claim 1, wherein the current-diffusion preventing layer includes the nitrogen-based compound semiconductor layer and an AlₓGa₁₋ₓAs layer having Al composition of 0.4 or more.

6. The current confining structure according to claim 1, further comprising a p-type semiconductor layer formed across the active layer from the n-type semiconductor layer,
the p-type semiconductor layer including a current diffusion layer promoting current in-plane diffusion.

7. The current confining structure according to claim 1, wherein the current confining layer is formed by selectively oxidizing an AlₓGa₁₋ₓAs semiconductor layer (0.95≦x≦1).

8. The current confining structure according to claim 1, wherein the current confining layer includes a current carrying layer formed of an n-type semiconductor and a p-type semiconductor current blocking layer formed around the current carrying layer.

9. A semiconductor laser, comprising:
a semiconductor substrate;
a p-type semiconductor layer and an n-type semiconductor layer laminated on a surface of the semiconductor substrate;
an active layer formed between the p-type semiconductor layer and the n-type semiconductor layer;
a current confining layer formed between the active layer and the n-type semiconductor layer and confining a current derived from n-type carriers moving from the n-type semiconductor layer to the active layer;
a current-diffusion preventing layer formed between the current confining layer and the active layer and including a nitrogen-based compound semiconductor layer obtained by substituting nitrogen atoms for a part of atoms of a base compound semiconductor; and
an optical resonator structure inducing laser oscillation.

10. The semiconductor laser according to claim 9, wherein the nitrogen-based compound semiconductor layer contains 0.05% or more of nitrogen.

11. The semiconductor laser according to claim 9, wherein the optical resonator structure includes semiconductor multilayer reflective films sandwiching the active layer, and
laser light is emitted vertically to the surface of the semiconductor substrate.

12. The semiconductor laser according to claim 9, wherein the p-type semiconductor layer includes a current diffusion layer promoting current in-plan diffusion, and
the current diffusion layer is formed at a node of light field intensity.

13. The currently confining structure according to claim 2, wherein the nitrogen-based compound semiconductor layer is formed of a material selected from the group consisting of GaAsN, AlGaNAs, and GaInNAs.

14. The current confining structure according to claim 3, wherein the nitrogen-based compound semiconductor layer contains 0.05% or more of nitrogen.

15. The current confining structure according to claim 3, wherein the current-diffusion preventing layer includes the nitrogen-based compound semiconductor layer and an AlxGa₁₋ₓAs layer having Al composition of 0.4 or more.

16. The current confining structure according to claim 4, wherein the current-diffusion preventing layer includes the nitrogen-based compound semiconductor layer and an AlₓGa₁₋ₓAs layer having Al composition of 0.4 or more.

17. The current confining structure according to claim 2, wherein the current confining layer is formed by selectively oxidizing an AlₓGa₁₋ₓAs semiconductor layer (0.95≦x≦1).

18. The current confining structure according to claim 3, wherein the current confining layer is formed by selectively oxidizing an AlₓGa₁₋ₓAs semiconductor layer (0.95≦x≦1).

19. The current confining structure according to claim 5, wherein the current confining layer is formed by selectively oxidizing an AlₓGa₁₋ₓAs semiconductor layer (0.95≦x≦1).

20. The current confining structure according to claim 2, wherein the current confining layer includes a current carrying layer formed of an n-type semiconductor and a p-type semiconductor current blocking layer formed around the current carrying layer.

21. The current confining structure according to claim 5, wherein the current confining layer includes a current carrying layer formed of an n-type semiconductor and a p-type semiconductor current blocking layer formed around the current carrying layer.

22. The semiconductor laser according to claim 10, wherein the optical resonator structure includes semiconductor multilayer reflective films sandwiching the active layer, and
laser light is emitted vertically to the surface of the semiconductor substrate.

23. The semiconductor laser according to claim 10, wherein the p-type semiconductor layer includes a current diffusion layer promoting current in-plane diffusion layer promoting current in-plane diffusion, and
the current diffusion layer is formed at a node of light field intensity.

24. The semiconductor laser according to claim 11, wherein the p-type semiconductor layer includes a current diffusion layer promoting current in-plane diffusion, and the current diffusion layer is formed at a node of light field intensity.
